(19) United States
(12) Patent Application Publication
(10) Pub. No.: US 2007/0121297 A1
(43) Pub. Date: May 31, 2007

(54) Display device provided with radiating structure and plasma display device provided with radiating structure

(75) Inventors: Tatsuya Uchizono, Echizen-city (JP); Koichi Tajima, Echizen-city (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: ORION ELECTRIC CO., LTD., Echizen-city (JP)

(21) Appl. No.: 11/605,461

(22) Filed: Nov. 29, 2006

(30) Foreign Application Priority Data
Nov. 30, 2005 (JP) 2005-346757

(51) Int. Cl. H05K 7/20

(52) U.S. Cl. 361/704

(57) ABSTRACT

A display device provided with a radiating structure for cooling heat of heat generating parts is provided. In a PDP device provided with a display panel which displays videos, reinforcement support members which reinforce the display panel fixed to an enclosure is made to contact heat generating parts which are heated in the enclosure and the reinforcement support members are made to have a dual-function as radiating members for radiating heat from the heat generating parts. This makes it possible to cool heat of the heat generating parts and suppress an increase in the number of parts and an increase in the manufacturing cost.

The present application is based on and claims priority of Japanese patent application No. 2005-346757 filed on Nov. 30, 2005, the entire contents of which are hereby incorporated by reference.

### BACKGROUND OF THE INVENTION

1. Field of the Invention

The present invention relates to a display device provided with a radiating structure, and more particularly, to a display device provided with a radiating structure for radiating heat from heat generating parts disposed inside a plasma display (PDP: Plasma Display Panel) device which is a display device and a PDP device provided with a radiating structure.

2. Description of the Related Art

A feature of a PDP device which is in use in recent years is that it generally has a large-screen display panel to display videos and a low-profile structure, that is, a small depth compared to its overall size. A typical product of such a low-profile display device is a liquid crystal television or the like, and in response to requirements for increasingly reduced thickness, space in the enclosures of these products is becoming more and more cramped and it is considered one of problems how to cool heat generated from electronic parts in the enclosure more efficiently.

Inside a PDP device, there are generally a plurality of circuit substrates provided with various functions and a scanning electrode drive circuit substrate and a common electrode drive circuit substrate which apply a voltage to a gas (helium, neon, xenon or a mixed gas containing these gases) sealed in a display panel and generate plasma discharge. The scanning electrode drive circuit substrate and the common electrode drive circuit substrate are generally installed on the back side of the display panel, a plurality of heat generating parts are arranged on the scanning electrode drive circuit substrate and the common electrode drive circuit substrate. The voltage for plasma discharge to be supplied to the gas sealed in the display panel is supplied from a power substrate which is different from the scanning electrode drive circuit substrate and the common electrode drive circuit substrate and these heat generating parts become hot, and therefore a conventional product is provided with a fan and a large radiating member exclusively for radiation to suppress temperature rise of the heat generating parts so as to cool heat from the heat generating parts. As a technology related to such a conventional technology, Japanese Patent Laid-Open Publication No. 2004-327841 (Patent Document 1) discloses an electronic apparatus which disposes a tabular heat sink on a heat generating electronic part fixed to a circuit substrate through a heat conductive member so as to make it possible to effectively cool heat from the heat generating electronic part by the heat sink.

However, in the case of the above described background technology, the large-sized radiating member must be installed to cool the heat generating parts, which may cause the number of parts to increase and lead to an increase in the manufacturing cost, producing a possibility that it may be impossible to suppress cost to an affordable level and the weight of the product may be increased. Furthermore, while Patent Document 1 describes the technology capable of cooling the heat generating electronic part by the heat sink, it neither suggests nor discloses use of a support plate or the like screwed together with a wiring substrate as a dual-function part to cool the heat generating electronic part.

### SUMMARY OF THE INVENTION

The present invention has been implemented in view of the above described problems and it is an object of the present invention to provide a display device provided with a radiating structure and a PDP device provided with a radiating structure capable of effectively cooling heat generating parts by attaching a separate large radiating member to cool the heat generating parts without increasing the number of parts or increasing manufacturing cost or increasing the product weight.

The display device provided with a radiating structure is a display device including a display panel which displays videos fitted in an enclosure, wherein reinforcement support members of the display panel fixed to the enclosure are made to contact heat generating parts which generate heat inside the enclosure and the reinforcement support members have a dual-function as a radiating member to radiate heat of the heat generating parts.

In the above configuration, heat of the heat generating parts in the enclosure is transmitted to the reinforcement support members attached for reinforcement of the display panel which contacts this heat generating parts and the reinforcement support members have a dual-function as a radiating member and radiate the heat transmitted from the heat generating parts.

The display device provided with a radiating structure has a radiating section which contacts the heat generating parts formed in the reinforcement support members as one unit.

In the above described configuration, the heat generating parts formed integral with the reinforcement support members and provided with, for example, a cooling fin are made to contact the heat generating parts and the reinforcement support members are made to transmit heat of the heat generating parts, and therefore it is possible to radiate heat effectively.

The display device provided with a radiating structure has a cooling fin and through holes or any one of a cooling fin and through holes formed in the reinforcement support members.

The above described configuration causes the surface area of the reinforcement support members to increase and allows heat of the heat generating parts to be radiated effectively. That is, by forming the cooling fin or through holes or both of them in the reinforcement support members, it is possible to increase the area of contact with the outside air for cooling heat from the heat generating parts which is transmitted to the reinforcement support members, in other words, to increase the area in contact with the air which can be radiated and thereby radiate heat transmitted to the reinforcement support members more effectively.

The display device provided with a radiating structure uses an aluminum alloy as the material of the reinforcement support members.

In the above described configuration, the aluminum alloy has higher heat conductivity than synthetic resin or the like, and can thereby radiate heat of the heat generating parts from the reinforcement support members more effectively.

The display device is a plasma display device, wherein the heat generating parts are disposed on a scanning electrode drive circuit substrate and a common electrode drive circuit substrate which constitute a circuit to generate plasma discharge by applying a voltage to a gas sealed in the display panel, and the reinforcement support members are made to contact the heat generating parts disposed on both the scanning electrode drive circuit substrate and the common electrode drive circuit substrate or any one of the scanning electrode drive circuit substrate and the common electrode drive circuit substrate.

In the above described configuration, when a voltage is applied to the gas sealed in the display panel, the scanning electrode drive circuit substrate and the common electrode drive circuit substrate generate plasma discharge, and this causes the heat generating parts disposed on the scanning electrode drive circuit substrate and the common electrode drive circuit substrate to become hot. In this case, since the heat generating parts disposed on both of the scanning electrode drive circuit substrate and the common electrode drive circuit substrate or any one of the scanning electrode drive circuit substrate and the common electrode drive circuit substrate contact the reinforcement support members, and therefore it is possible to radiate heat of the heat generating parts generated by plasma discharge from the reinforcement support members and prevent the scanning electrode drive circuit substrate and the common electrode drive circuit substrate from becoming hot.

### BRIEF DESCRIPTION OF THE DRAWINGS

FIG. 1 is a rear view of a display device showing an embodiment of the present invention with an enclosure removed;

FIG. 2 is a sectional view of the display device according to the embodiment of the present invention viewed from the right side;

FIG. 3 is a perspective view showing a reinforcement support member attached to the enclosure according to the embodiment of the present invention; and

FIG. 4 is a perspective view showing a modification example of the reinforcement support member according to the embodiment of the present invention.

### DETAILED DESCRIPTION OF THE PREFERRED EMBODIMENTS

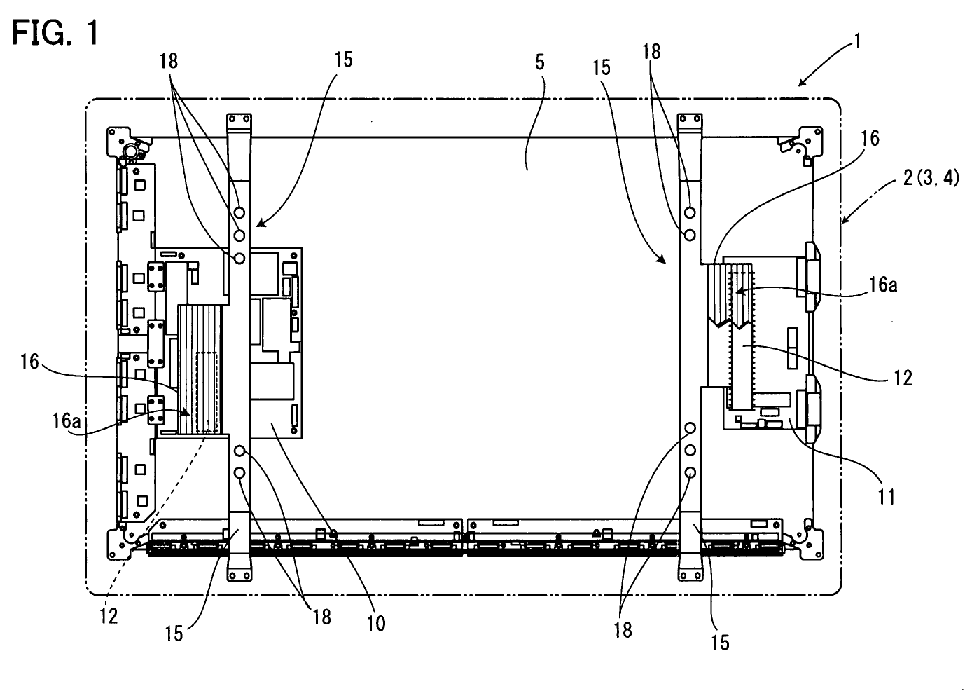

Hereinafter, as the best mode for implementing the present invention, an embodiment will be explained with reference to FIG. 1 to FIG. 4. It goes without saying that the present invention is also easily applicable to modes other than that explained in the embodiment within a range not departing from the essence of the present invention.

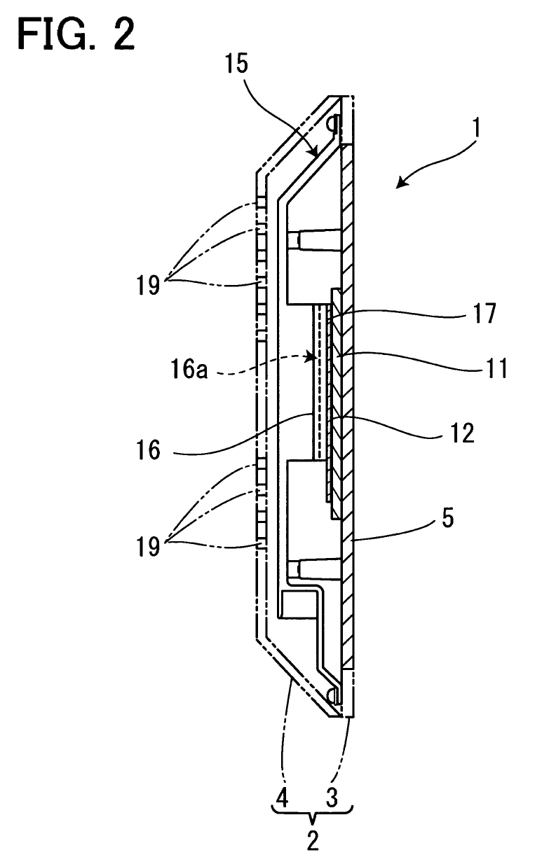

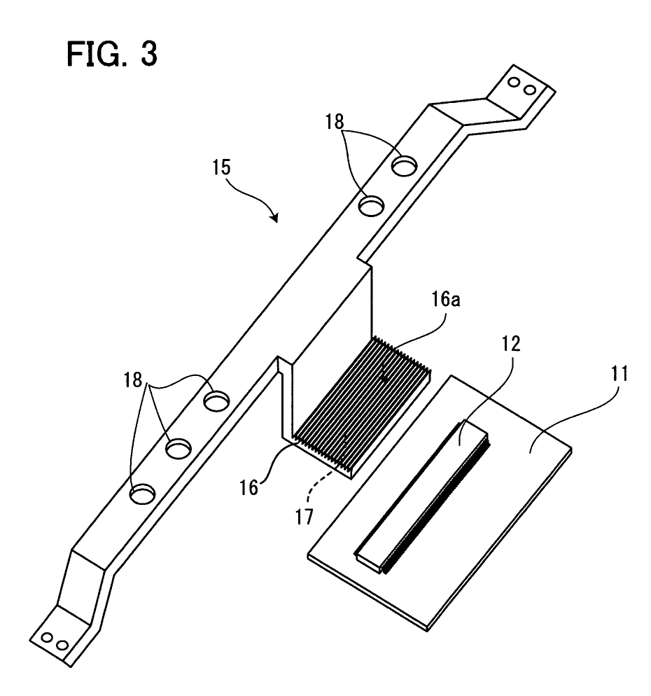

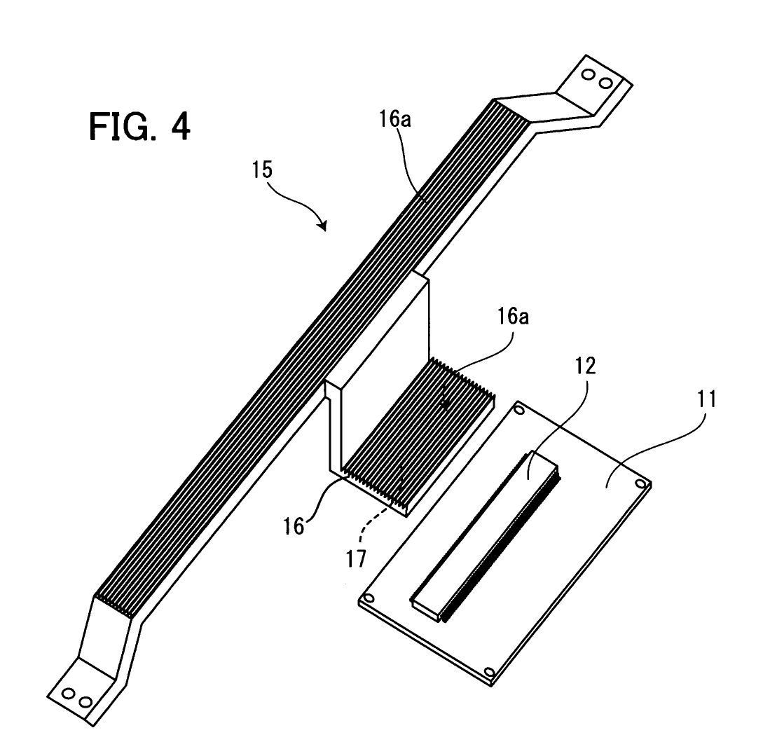

FIG. 1 is a rear view of a display device showing an example of the present invention with an enclosure removed, FIG. 2 is a sectional view of the display device viewed from the right side, FIG. 3 is a perspective view showing a reinforcement support member attached to the enclosure and FIG. 4 is a perspective view showing a modification example of the reinforcement support member.

An enclosure 2 made of resin of a PDP (Plasma Display Panel) device 1 which is the display device according to this embodiment is constructed of a front cabinet 3 and a back cabinet 4 combined as one unit and a display panel 5 which displays videos is fitted in on the front side of the front cabinet 3.

The display panel 5 is large enough to display a video in a relatively large size screen of approximately 40 inches or greater, featuring a low-profile structure with a small depth compared to its whole shape. A plurality of circuit substrates having various functions are provided inside the enclosure 2 of the PDP device 1, wherein a scanning electrode drive circuit substrate 10 and a common electrode drive circuit substrate 11 which constitute a circuit for applying a voltage to a gas (helium, neon, xenon or mixed gas containing these gases or the like) sealed in the display panel 5 and generating plasma discharge are mounted in the enclosure 2. The scanning electrode drive circuit substrate 10 and the common electrode drive circuit substrate 11 are attached to the back side of the display panel 5 parallel to each other as shown in FIG. 1, a heat generating part 12 is provided for each of the scanning electrode drive circuit substrate 10 and the common electrode drive circuit substrate 11 and the heat generating parts 12 are heated to high temperature when a voltage for discharging the gas which is sealed in the display panel 5 is supplied from a power substrate (not shown) to the scanning electrode drive circuit substrate 10 and the common electrode drive circuit substrate 11.

Furthermore, reinforcement support members 15 which are internal components of the PDP device 1 are fixed by screws to the front cabinet 3 in parallel at a predetermined distance from each other and the material thereof is an aluminum alloy with high heat conductivity, and since the heat generating parts 12 disposed on the scanning electrode drive circuit substrate 10 and the common electrode drive circuit substrate 11 contact radiating sections 16 which have cooling fins 16a formed integral with the reinforcement support members 15, heat of the heat generating parts 12 is transmitted to the reinforcement support members 15, thus suppressing transmission of heat of the scanning electrode drive circuit substrate 10 and the common electrode drive circuit substrate 11 and allowing the support members 15 to radiate heat from the heat generating parts 12.

The reinforcement support member 15 will be further explained here based on FIG. 3. This reinforcement support member 15 is molded through aluminum die-cast and the above described cooling fin 16a which is sawtooth-shaped and extends on the opposite side of a contact surface 17 which contacts the heat generating part 12 is formed integral therewith, and forming the cooling fin 16a not into a tabular shape but in such a way as to have a large surface area to effectively radiate heat transmitted from the heat generating part 12 to the radiating section 16 through the cooling fin 16a and the whole reinforcement support member 15 forming this cooling fin 16a can prevent temperature rise in the enclosure 2. In this way, for the heat generating parts 12 disposed on the scanning electrode drive circuit substrate 10 and the common electrode drive circuit substrate 11, this embodiment causes the reinforcement support members 15 for reinforcement of the PDP device 1 to have a dual-function as radiating members so as to be able to cool the heat generating parts 12, and can thereby eliminate the necessity for a large-sized radiating member which would be conventionally required separately for only cooling purposes, reduce the number of parts, reduce the cost of the PDP device 1 and also realize a weight reduction.

Furthermore, using an aluminum alloy with high heat conductivity as the material of the reinforcement support members 15 which are existing components allows heat of the heat generating parts 12 disposed on the scanning electrode drive circuit substrate 10 and the common electrode drive circuit substrate 11 for generating plasma discharge of the gas sealed in the display panel 5 to be radiated from the reinforcement support members 15 more effectively. Therefore, heat is hardly confined in the enclosure 2 of the PDP device 1, and moreover since holes 19 are formed in the back cabinet 4, it is possible to cool heat of the heat generating parts 12 inside the PDP device 1 and discharge heat out of the PDP device 1 through the holes 19 and even when an electronic part susceptible to heat is provided in the enclosure 2, it is possible to prevent malfunction caused by heating of the electronic part.

Furthermore, since the radiating sections 16 which directly contact the heat generating parts 12 disposed on the scanning electrode drive circuit substrate 10 and the common electrode drive circuit substrate 11 are formed integral with the reinforcement support members 15, it is possible to improve the efficiency of heat conductivity compared to a structure whereby heat is radiated after transmitting heat through a plurality of members. In addition, by causing the radiating sections 16 to directly contact the heat generating parts 12 and providing the cooling fins 16a on the opposite side of the contact surface 17 which contacts the heat generating parts 12, it is possible to shorten the distance between the heat generating parts 12 and cooling fins 16a which have a high cooling effect and cause heat to transmit from the heat generating parts 12 to the cooling fins 16a more effectively.

For the reinforcement support members 15, this embodiment adopts the shape with five through holes 18 to increase a surface area which contacts the air in the enclosure 2, but increasing the number of through holes 18 within a range satisfying the strength for reinforcement of the display panel 5 of the PDP device 1 which is the original purpose of the reinforcement support members 15 can further increase the surface area of the support members 15 and increasing the surface area allows heat of the heat generating parts 12 to be radiated more effectively.

This embodiment forms the cooling fin 16a on the opposite side of the contact surface 17 of the radiating section 16 which contacts the heat generating part 12, but in addition to this cooling fin 16a, if a cooling fin 16a is formed at any location of the reinforcement support members 15 other than the opposite side of the contact surface 17 as in the case of a modification example shown with FIG. 4, it is possible to further improve the cooling effect.

As described above, this embodiment forms the radiating sections 16 which contact the heat generating parts 12 disposed on the scanning electrode drive circuit substrate 10 and the common electrode drive circuit substrate 11 integral with the reinforcement support members 15 which are attached to reinforce the strength of the display panel 5 of the PDP device 1, thereby allows the reinforcement support members 15 to have a dual-function as the radiating members, and can thereby effectively radiate and cool heat of the heat generating parts 12 disposed on the scanning electrode drive circuit substrate 10 and the common electrode drive circuit substrate 11 or the like. As a result, it is possible to eliminate the necessity for a large-sized radiating member used for the purpose of cooling heat of the heat generating parts disposed on the conventional circuit substrate, reduce the number of parts and thereby reduce the cost of the PDP device 1. In addition, the work for attaching a radiating member is no longer necessary and work processes can be shortened. Moreover, together with the reduction of the relatively large-sized conventional radiating member, the space in the PDP device 1 can be widened and the thickness- of the PDP device 1 can be further reduced. Moreover, since the reinforcement support members 15 are arranged in the neighborhood of the back cabinet 4, it is possible to discharge heat transmitted by the heat generating parts 12 to the reinforcement support members 15 to the outside of the PDP device 1 while radiating the heat from the reinforcement support members 15 through the plurality of holes 19 formed in the back cabinet 4 without the heat being confined inside the PDP device 1.

Note that in a normal usage condition of the PDP device 1, that is, in a condition in which the front side of the display panel 5 on which videos are displayed becomes substantially vertical when the PDP device 1 is placed, the reinforcement support members 15 are attached to the front cabinet 3 at the top edge and bottom edge of the display panel 5 in such a way that the both ends of the reinforcement support members 15 in the longitudinal direction thereof are fixed and the reinforcement support members 15 disposed on the back of the PDP device 1 are formed into a substantially trapezoid shape with both ends in the longitudinal direction thereof being bent toward the front of the PDP device 1 so that the reinforcement support members 15 do not contact the scanning electrode drive circuit substrate 10 and the common electrode drive circuit substrate 11 mounted inside the enclosure 2.

The effects of the present invention are as follows.

The display device provided with a radiating structure according to an aspect of the present invention is a display device including a display panel which displays videos fitted in an enclosure, wherein reinforcement support members of the display panel fixed to the enclosure are made to contact heat generating parts which generate heat inside the enclosure and the reinforcement support members have a dual-function as a radiating member to radiate heat of the heat generating parts, and therefore it is possible to cool heat of the heat generating parts using the reinforcement support members.

According to the display device provided with a radiating structure according to another aspect of the present invention, a radiating section which contacts the heat generating parts is formed in the reinforcement support members as one unit, and therefore it is possible to cause the radiating section provided with the cooling fan or the like to transmit heat of the heat generating parts and cause the reinforcement support members to effectively cool heat of the heat generating parts.

According to the display device provided with a radiating structure according to a further aspect of the present invention, a cooling fin and through holes or any one of a cooling fin and through holes are formed in the reinforcement support members, and therefore the surface area of the reinforcement support members increases, making it possible to increase the area of contact with the air and more efficiently cool heat of the heat generating parts.

According to the display device provided with a radiating structure according to a still further aspect of the present invention, an aluminum alloy is used as the material of the reinforcement support members, and since the characteristic of an aluminum alloy has higher heat conductivity than, for example, synthetic resin, and therefore it is possible to effectively cool heat of the heat generating parts using the reinforcement support members.

According to the plasma display device provided with a radiating structure according to a still further aspect of the present invention, the display device is a plasma display device, the heat generating parts are disposed on a scanning electrode drive circuit substrate and a common electrode drive circuit substrate which constitute a circuit to generate plasma discharge by applying a voltage to a gas sealed in the display panel, and the reinforcement support members are made to contact the heat generating parts disposed on both the scanning electrode drive circuit substrate and the common electrode drive circuit substrate or any one of the scanning electrode drive circuit substrate and the common electrode drive circuit substrate, and therefore it is possible to cool heat of the heat generating parts generated by plasma discharge using the reinforcement support members, prevent the scanning electrode drive circuit substrate and the common electrode drive circuit substrate from becoming hot as much as possible and avoid problems such as malfunction caused by high temperature even when a part which is not resistant to high temperature is disposed on the scanning electrode drive circuit substrate and the common electrode drive circuit substrate.

1. A display device provided with a radiating structure, comprising a display panel which displays videos fitted in an enclosure, wherein reinforcement support members of the display panel fixed to the enclosure are made to contact heat generating parts which generate heat inside the enclosure and the reinforcement support members have a dual-function as radiating members to radiate heat of the heat generating parts.

2. The display device provided with a radiating structure according to claim 1, wherein a radiating section which contacts the heat generating part is formed in the reinforcement support members as one unit.

3. The display device provided with a radiating structure according to claim 1, wherein cooling fins and through holes or any one of cooling fins and through holes are formed in the reinforcement support members.

4. The display device provided with a radiating structure according to claim 1, wherein an aluminum alloy is used as the material of the reinforcement support members.

5. A plasma display device comprising the radiating structure according to claim 1,
wherein the display device is a plasma display device,
the heat generating parts are disposed on a scanning electrode drive circuit substrate and a common electrode drive circuit substrate which constitute a circuit to generate plasma discharge by applying a voltage to a gas sealed in the display panel, and
the reinforcement support members are made to contact the heat generating parts disposed on both the scanning electrode drive circuit substrate and the common electrode drive circuit substrate or any one of the scanning electrode drive circuit substrate and the common electrode drive circuit substrate.

6. The display device provided with a radiating structure according to claim 2, wherein cooling fins and through holes or any one of cooling fins and through holes are formed in the reinforcement support members.

7. The display device provided with a radiating structure according to claim 2, wherein an aluminum alloy is used as the material of the reinforcement support members.

8. The display device provided with a radiating structure according to claim 3, wherein an aluminum alloy is used as the material of the reinforcement support members.

9. The display device provided with a radiating structure according to claim 6, wherein an aluminum alloy is used as the material of the reinforcement support members.

10. A plasma display device comprising the radiating structure according to claim 2,
wherein the display device is a plasma display device,
the heat generating parts are disposed on a scanning electrode drive circuit substrate and a common electrode drive circuit substrate which constitute a circuit to generate plasma discharge by applying a voltage to a gas sealed in the display panel, and
the reinforcement support members are made to contact the heat generating parts disposed on both the scanning electrode drive circuit substrate and the common electrode drive circuit substrate or any one of the scanning electrode drive circuit substrate and the common electrode drive circuit substrate.

11. A plasma display device comprising the radiating structure according to claim 3,
wherein the display device is a plasma display device,
the heat generating parts are disposed on a scanning electrode drive circuit substrate and a common electrode drive circuit substrate which constitute a circuit to generate plasma discharge by applying a voltage to a gas sealed in the display panel, and
the reinforcement support members are made to contact the heat generating parts disposed on both the scanning electrode drive circuit substrate and the common electrode drive circuit substrate or any one of the scanning electrode drive circuit substrate and the common electrode drive circuit substrate.

12. A plasma display device comprising the radiating structure according to claim 4,
wherein the display device is a plasma display device,
the heat generating parts are disposed on a scanning electrode drive circuit substrate and a common electrode drive circuit substrate which constitute a circuit to generate plasma discharge by applying a voltage to a gas sealed in the display panel, and
the reinforcement support members are made to contact the heat generating parts disposed on both the scanning electrode drive circuit substrate and the common electrode drive circuit substrate or any one of the scanning electrode drive circuit substrate and the common electrode drive circuit substrate.

13. A plasma display device comprising the radiating structure according to claim 6,
wherein the display device is a plasma display device,
the heat generating parts are disposed on a scanning electrode drive circuit substrate and a common electrode drive circuit substrate which constitute a circuit to generate plasma discharge by applying a voltage to a gas sealed in the display panel, and
the reinforcement support members are made to contact the heat generating parts disposed on both the scanning electrode drive circuit substrate and the common electrode drive circuit substrate or any one of the scanning electrode drive circuit substrate and the common electrode drive circuit substrate.

14. A plasma display device comprising the radiating structure according to claim 7,
wherein the display device is a plasma display device,
the heat generating parts are disposed on a scanning electrode drive circuit substrate and a common electrode drive circuit substrate which constitute a circuit to generate plasma discharge by applying a voltage to a gas sealed in the display panel, and
the reinforcement support members are made to contact the heat generating parts disposed on both the scanning electrode drive circuit substrate and the common electrode drive circuit substrate or any one of the scanning electrode drive circuit substrate and the common electrode drive circuit substrate.

15. A plasma display device comprising the radiating structure according to claim 8,
wherein the display device is a plasma display device,
the heat generating parts are disposed on a scanning electrode drive circuit substrate and a common electrode drive circuit substrate which constitute a circuit to generate plasma discharge by applying a voltage to a gas sealed in the display panel, and
the reinforcement support members are made to contact the heat generating parts disposed on both the scanning electrode drive circuit substrate and the common electrode drive circuit substrate or any one of the scanning electrode drive circuit substrate and the common electrode drive circuit substrate.

16. A plasma display device comprising the radiating structure according to claim 9,
wherein the display device is a plasma display device,
the heat generating parts are disposed on a scanning electrode drive circuit substrate and a common electrode drive circuit substrate which constitute a circuit to generate plasma discharge by applying a voltage to a gas sealed in the display panel, and
the reinforcement support members are made to contact the heat generating parts disposed on both the scanning electrode drive circuit substrate and the common electrode drive circuit substrate or any one of the scanning electrode drive circuit substrate and the common electrode drive circuit substrate.
